(19) United States
(12) Patent Application Publication
(10) Pub. No.: US 2024/0222556 A1
(43) Pub. Date: Jul. 4, 2024

(54) DISPLAY PANEL, METHOD FOR FABRICATING DISPLAY PANEL, AND DISPLAY DEVICE

(71) Applicant: SHANGHAI TIANMA MICROELECTRONICS CO., LTD., Shanghai (CN)

(72) Inventors: Jiaxian LIU, Shanghai (CN); Ming YANG, Shanghai (CN); Ping AN, Shanghai (CN); Quanpeng YU, Shanghai (CN); Feng YU, Shanghai (CN)

(73) Assignee: SHANGHAI TIANMA MICROELECTRONICS CO., LTD., Shanghai (CN)

(21) Appl. No.: 18/429,456

(22) Filed: Feb. 1, 2024

(30) Foreign Application Priority Data
Jun. 30, 2023 (CN) 202310801649.2

(51) Int. Cl. H01L 33/38; H01L 25/16

(52) U.S. Cl. CPC H01L 33/38; H01L 25/167; H01L 2933/0016

(57) ABSTRACT

A display panel, a method for fabricating the display panel and a display device are provided to improve reliability of the display panel. The display panel includes an array layer, one or more light-emitting devices arranged on the array layer, a first film layer at least partially arranged on the one or more light-emitting devices, and a first electrode arranged on the first film layer. Openings are formed on the first film layer, and at least part of the openings overlap the respective light-emitting devices. The display device including the display panel and the method for fabricating the display panel are further provided.

The present application claims priority to Chinese Patent Application No. 202310801649.2, titled “DISPLAY PANEL, METHOD FOR FABRICATING DISPLAY PANEL, AND DISPLAY DEVICE”, filed on Jun. 30, 2023 with the China National Intellectual Property Administration, which is incorporated herein by reference in its entirety.

### FIELD

The present disclosure relates to the field of displays, and in particular to a display panel, a method for fabricating the display panel and a display device.

### BACKGROUND

As display technology develops by leaps and bounds, display panels are widely used in various aspects. Micro-light-emitting diodes (micro-LED) have high efficiency, high brightness, high reliability, rapid response, and are self-emitting. Further, the micro-LED has advantages such as energy conservation, simple structure, small size, and is thin, and thus is widely applied in the field of displays. However, there are still some problems to be urgently addressed.

### SUMMARY

In view of this, a display panel and a display device are provided according to the present disclosure.

The display panel according to the present disclosure includes an array layer, one or more light-emitting devices arranged on the array layer, a first film layer arranged on the one or more light-emitting devices, and a first electrode arranged on the first film layer. Openings are formed on the first film layer, and at least part of the openings overlap the respective light-emitting devices.

The display device according to the present disclosure includes the foregoing display panel.

A method for fabricating the display panel is further provided according to the present disclosure. The method includes: providing an array layer; arranging one or more light-emitting devices on the array layer; arranging a first film layer on the light-emitting devices; forming openings on the first film layer, where at least part of the openings overlap the respective light-emitting devices; and arranging a first electrode on the first film layer.

According to the present disclosure, the reliability of the display panel can be improved.

### BRIEF DESCRIPTION OF THE DRAWINGS

FIG. 1 shows a top view of a display panel according to an embodiment of the present disclosure;

FIG. 2 is a schematic diagram showing an active area partially enlarged as illustrated in FIG. 1;

FIG. 3 is a schematic diagram partially showing the display panel in cross-section along a line AA′ as shown in FIG. 2;

FIG. 4 is a schematic diagram illustrating a light-emitting device and a display panel that are partially enlarged according to an embodiment of the present disclosure;

FIG. 5 is a schematic diagram showing the active area partially enlarged as illustrated in FIG. 1 according to another embodiment;

FIG. 6 is a schematic diagram partially showing the display panel in cross-section along a line AA′ as shown in FIG. 5;

FIG. 7 is a schematic diagram partially showing the display panel in cross-section along the line AA′ as shown in FIG. 5 according to another embodiment;

FIG. 8 is a schematic diagram partially showing the display panel in cross-section along the line AA′ as shown in FIG. 5 according to another embodiment;

FIG. 9 is a schematic diagram partially showing the display panel in cross-section along the line AA′ as shown in FIG. 5 according to another embodiment;

FIG. 10 is a schematic diagram showing the active area partially enlarged according to another embodiment;

FIG. 11 is a schematic diagram partially showing the display panel in cross-section along the line AA′ as shown in FIG. 10;

FIGS. 12 to 14 each are a schematic diagram partially showing the display panel in cross-section along the line AA′ as shown in FIG. 5 or 10;

FIG. 15 is a schematic diagram illustrating patterning of openings according to an embodiment;

FIG. 16 is a schematic diagram partially showing the display panel in cross-section along the line AA′ as shown in FIG. 15;

FIGS. 17 to 19 each are a schematic diagram partially showing the display panel in cross-section along the line AA′ as shown in FIG. 5 or 10;

FIG. 20 is a schematic diagram illustrating patterning of openings according to another embodiment;

FIGS. 21 and 22 each are a schematic diagram partially showing the display panel in cross-section along the line AA′ as shown in FIG. 5 or 10; and

FIG. 23 is a schematic diagram illustrating a display device according to an embodiment of the present disclosure.

### DETAILED DESCRIPTION

In order to make the embodiments of the present disclosure more apparent and understandable, the present disclosure is further described below in conjunction with the drawings and embodiments.

It should be noted that details are provided in the following description to facilitate a full understanding of the present disclosure. However, the present disclosure may be implemented in various ways different from the ways described herein. Therefore, the present disclosure is not limited by the embodiments disclosed below.

Terms used in the present disclosure are only used for describing specific embodiments rather than limiting the present disclosure. The terms “a”, “said”, and “the” in a singular form used in the present disclosure and the claims are intended to include a plural form unless other meanings are clearly indicated in the context.

It should be noted that the directional words such as “up”, “down”, “left”, and “right” in the embodiments of the present disclosure are described based on the perspectives shown in the drawings, and should not be construed as limitations to the embodiments of the present disclosure. In addition, it should also be understood that one element, when described as being formed “on” or “under” the other element, may be directly or indirectly formed “on” or “under” the other element.

In one embodiment, the exemplary embodiments may be implemented in multiple manners and should not be understood as limitations to the implementations described herein. Instead, these embodiments are provided and the present disclosure is more comprehensive and complete, and the concept of the exemplary embodiments is comprehensively conveyed. The same reference numeral in the drawings represents the same or similar structures, and therefore is not repeated. The terms for describing positions and directions in the present disclosure are illustrated with the drawings as examples. However, changes may be made as required, and all the changes are within the protection scope of the present disclosure. The drawings in the present disclosure are only used to illustrate relative position relationship, and layer thicknesses of some parts are illustrated in an exaggerative manner to facilitate the understanding. The layer thicknesses in the drawings do not represent a proportional relationship of an actual layer thickness. In addition, the embodiments of the present disclosure and features in the embodiments may be combined with each other in case of no conflict. Throughout the drawings of the embodiments of the present disclosure, same components are denoted by same reference numerals. Furthermore, features common to the various embodiments are not repeated.

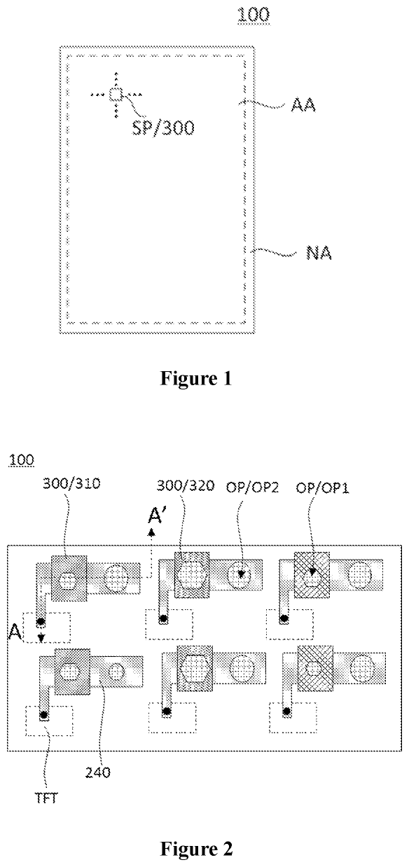

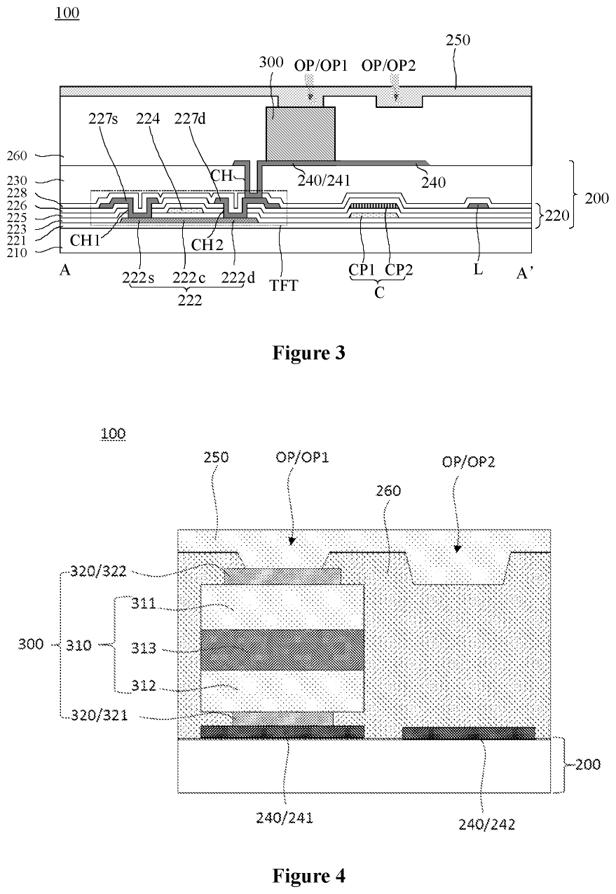

FIG. 1 is a top view of a display panel according to an embodiment of the present disclosure. FIG. 2 is a schematic diagram showing an active area partially enlarged as illustrated in FIG. 1. FIG. 3 is a schematic diagram partially showing the display panel in cross-section along a line AA′ as shown in FIG. 2. The cross-section is perpendicular to a plane where the display panel extends.

In some embodiments, a display panel 100 includes an active area AA and a non-active area NA surrounding the active area AA. It can be understood that a dashed box in FIG. 1 represents a boundary between the active area AA and the non-active area NA. The active area AA of the display panel is configured to display an image, and generally includes multiple pixels sp arranged in an array. The multiple pixels sp are provided with respective light-emitting devices (for example, diodes) and a control element (for example, a thin film transistor for forming a pixel driving circuit). The non-active area NA surrounds the active area AA, and generally includes a peripheral driving component, wiring, and a fan-out area.

In some embodiments, the display panel 100 includes a substrate 210.

In some embodiments, the substrate 210 is made of polymer material, such as glass, polyimide (PI), polycarbonate (PC), polyethersulfone (PES), polyethylene terephthalate (PET), polyethylene naphthalate (PEN), polyarylate (PAR), or fiber reinforced polymer (FRP). The substrate 210 is transparent, semi-transparent, or opaque.

In some embodiments, the substrate 210 is flexible or rigid. It should be noted that a film layer being described as arranged “on” a reference film layer throughout the embodiments of the present disclosure may be understood as arranged “on a side of the reference film layer away from the substrate”. Unless otherwise specified, “on” only represents an orientation relationship instead of necessitating that the two film layers are adjacent or in contact.

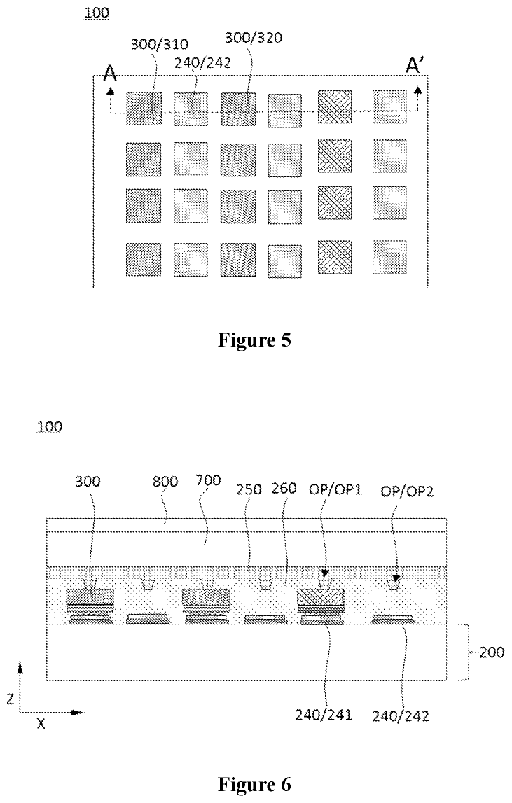

An array layer 200 is arranged on a side of the substrate 210 facing a display surface or a touch surface of the display panel 100. In some embodiments, the array layer 200 as shown in FIG. 3 is detailed in FIG. 5 or other embodiments of the present disclosure.

In some embodiments, the array layer 200 further includes a driving circuit layer 220. The driving circuit layer is arranged on the substrate 210.

In some embodiments, the driving circuit layer 220 includes a thin film transistor TFT, a capacitor C, and wiring L.

For example, the driving circuit layer 220 is formed by a buffer layer 221, an active pattern 222, a gate insulation layer 223, a gate 224, an intermediate dielectric layer 225, an interlayer dielectric layer 226, a source 227s, a drain 227d, and a passivation layer 228.

The buffer layer 221 prevents impurities such as oxygen and moisture from permeating through the substrate 210, and flattens the substrate 210. In addition, the buffer layer 221 controls heat transfer in an annealing process when forming the active pattern 222. The buffer layer 221 is in a laminated structure made of one or more of silicon oxide, silicon nitride, silicon oxynitride and other inorganic material.

The driving circuit layer 220 includes multiple thin film transistors TFT, which form a pixel circuit corresponding to the light-emitting devices.

In the embodiments of the present disclosure, a top-gate thin film transistor is illustrated. The thin film transistor TFT includes the active pattern 222 arranged on the substrate 210. The active pattern 222 is made of a silicon semiconductor or an oxide semiconductor.

The silicon semiconductor includes one or more of amorphous silicon, monocrystalline silicon, and polycrystalline silicon. For example, the active pattern 222 is made of low-temperature polycrystalline silicon.

The active pattern 222 made of the polycrystalline silicon is formed from low-temperature amorphous silicon. That is, the amorphous silicon is converted into the polycrystalline silicon by laser, or rapid thermal annealing (RTA), solid-phase crystallization (SPC), excimer laser annealing (ELA), metal induced crystallization (MIC), metal induced lateral crystallization (MILC), or sequential lateral solidification (SLS).

The active pattern 222 further includes a source area, a drain area and a channel area between the source area and the drain area. The source area and the drain area are doped with an N-type impurity or P-type impurity.

In some embodiments, the active pattern 222 is made of the oxide semiconductor. The oxide semiconductor is made from indium (In), zinc (Zn), gallium (Ga), tin (Sn), titanium (Ti), aluminum (Al), hafnium (Hf), zirconium (Zr), magnesium (Mg), and the like. The active pattern 222 is made of binary compound, ternary compound, or quaternary compound. For example, the active pattern 222 is made of one or more of indium gallium zinc oxide (IGZO), indium tin zinc oxide (ITZO), gallium zinc oxide (GaZnxOy), indium zinc oxide (IZO), zinc magnesium oxide (ZnMgxOy), zinc oxide (ZnOx), gallium oxide (GaOx), tin oxide (SnOx), indium oxide (InOx), indium gallium hafnium oxide (IGHO), tin aluminum zinc oxide (TAZO), indium gallium tin oxide (IGTO), and the like. In the embodiments of the present disclosure, the oxide semiconductor described above is doped with lithium (Li), sodium (Na), manganese (Mn), nickel (Ni), palladium (Pd), copper (Cu), carbon (C), nitrogen (N), phosphorus (P), titanium (Ti), zirconium (Zr), vanadium (V), ruthenium (Ru), germanium (Ge), tin (Sn), fluorine (F), or the like.

In some embodiments, the gate insulation layer 223 is arranged on the active pattern 222. The gate insulation layer 223 includes an inorganic layer, for example, made of silicon oxide or silicon nitride. The gate insulation layer 223 is one or more in number.

In some embodiments, the gate 224 is arranged on the gate insulation layer 223. The gate 224 is one or more in number, and is made of gold (Au), silver (Ag), copper (Cu), nickel (Ni), platinum (Pt), palladium (Pd), aluminum (Al), molybdenum (MO), chromium (Cr), an alloy of aluminum (Al) and neodymium (Nd), or an alloy of molybdenum (MO) and tungsten (W).

The intermediate dielectric layer 225 covers the gate 224 and is arranged on the gate insulation layer 223. The intermediate dielectric layer 225 is in a laminated structure made of one or more of silicon oxide, silicon nitride, silicon oxynitride and other inorganic material. For example, the intermediate dielectric layer 225 is made of silicon nitride.

The interlayer dielectric layer 226 is arranged on the intermediate dielectric layer 225, for example. The interlayer dielectric layer 226 is in a laminated structure made of one or more of silicon oxide, silicon nitride, silicon oxynitride and other inorganic material.

The source 227s is in contact with a source area 222s of the active pattern 222. The drain 227d is in contact with a drain area 222d of the active pattern 222. The source 227s and the drain 227d are fabricated in a same process, and are arranged in a same film layer, for example. In some embodiments, a first contact opening CH1 for partially exposing the source area 222s and a second contact opening CH2 for partially exposing the drain area 222d each are defined through the gate insulation layer 223, the intermediate dielectric layer 225, and the interlayer dielectric layer 226. The source 227s is in contact with an upper surface of the source area 222s through the first contact hole CH1. The drain 227d is in contact with an upper surface of the drain area 222d through the second contact hole CH2. The source 227s and the drain 227d each are made of aluminum (Al), silver (Ag), chromium (Cr), titanium (Ti), tantalum (Ta), molybdenum (Mo), aluminum alloy, silver alloy, chromium alloy, titanium alloy, tantalum alloy, molybdenum alloy, aluminum nitride, silver nitride, chromium nitride, titanium nitride, tantalum nitride, molybdenum nitride, metal oxide, transparent electrically conductive material, or the like. For example, the source 227s and the drain 227d each are in a laminated structure made of metal including Ti/Al/Ti.

The passivation layer 228 covers the source 227s and the drain 227d, and is arranged on the interlayer dielectric layer 226. The passivation layer 228 is in a laminated structure made of one or more of silicon oxide, silicon nitride, silicon oxynitride and other inorganic material. For example, the passivation layer 228 is made of silicon nitride.

The capacitor C includes a first electrode plate CP1 and a second electrode plate CP2 that are arranged opposite to each other. The capacitor C is configured to maintain a node potential in a driving circuit. The first electrode plate CP1 is arranged between the gate insulation layer 223 and the intermediate dielectric layer 225. The first electrode plate CP1 and the gate 224 are arranged in the same film layer, and are made of the same material. The second electrode plate CP2 is arranged between the intermediate dielectric layer 225 and the interlayer dielectric layer 226. The second electrode plate CP2 is made of aluminum (Al), silver (Ag), chromium (Cr), titanium (Ti), tantalum (Ta), molybdenum (Mo), aluminum alloy, silver alloy, chromium alloy, titanium alloy, tantalum alloy, molybdenum alloy, aluminum nitride, silver nitride, chromium nitride, titanium nitride, tantalum nitride, molybdenum nitride, metal oxide, transparent electrically conductive material, or the like. For example, the second electrode plate CP2 is made of molybdenum (Mo).

The wiring L is configured to transmit various signals. For example, as shown in FIG. 3, the wiring L is arranged between the interlayer dielectric layer 226 and the passivation layer 228. In some embodiments, the wiring L, the source 227s and the drain 227d are arranged in the same film layer, and are made of the same material. In one embodiment, the wiring L is arranged in one film layer or distributed among multiple film layers, depending on types and requirements of signals to be transmitted. In some embodiments, the wiring L and the gate 224 are arranged in the same film layer. In other embodiments, the wiring L and the second electrode plate CP2 are arranged in the same film layer.

It should be understood that the driving circuit layer 220 includes a driving circuit. The driving circuit is configured to drive a light-emitting device 300 to emit light. In some embodiments, the driving circuit includes a pixel circuit. The pixel circuit is electrically connected to the light-emitting device 300, to drive the light-emitting device 300 to emit light.

As shown in the above diagrams, the array layer 200 further includes a planarization layer 230. The planarization layer 230 is arranged on the driving circuit layer 220. The planarization layer 230 is configured to form a flat surface on the driving circuit layer 220. In some embodiments, the planarization layer 230 is arranged on the passivation layer 228, and an upper surface of the planarization layer 230 away from the passivation layer 228 is substantially flat. The planarization layer 230 is made of organic material, such as photoresist, polyacrylate based resin, polyimide-based resin, polyamide-based resin, siloxane-based resin, acrylic based resin, or epoxy-based resin.

In some embodiments, the planarization layer 230 is at least two in number. Other electrically conductive layer or other metal layer is arranged between the two planarization layers 230 for transition or bridge function, to electrically connect the thin film transistor TFT and the light-emitting device 300.

The driving circuit layer 220 is laminated. an upper surface of the driving circuit layer 220 is uneven due to the active pattern 222, the gate 224, the source 227s, the drain 227d and the like that form the thin film transistor TFT, the capacitor C, and the wiring L in the driving circuit layer 220 as well as through holes (for example, the first contact hole CH1 and the second contact hole CH2) through the film layers. An upper surface of the passivation layer 228 serves as the upper surface of the driving circuit layer 220. The planarization layer 230 provides a flat surface for subsequently fabricated components.

It should be noted that in some embodiments, the planarization layer 230 doubles as an auxiliary film layer 280.

As shown in FIG. 3, the array layer 200 may further include a connection part 240. The connection part 240 is arranged on the planarization layer 230.

In some embodiments, the connection part 240 includes a first connection part 241. The first connection part 241 is electrically connected to the thin film transistor TFT in the driving circuit layer 220. For example, the first connection part 241 is electrically connected to the drain 227d of the thin film transistor TFT through a contact hole CH. The contact hole CH extends through the planarization layer 230 and the passivation layer 228, and partially exposes the drain 227d of the thin film transistor TFT. The connection part 240 is made of, for example, aluminum (Al), silver (Ag), chromium (Cr), titanium (Ti), tantalum (Ta), molybdenum (Mo), aluminum alloy, silver alloy, chromium alloy, titanium alloy, tantalum alloy, molybdenum alloy, aluminum nitride, silver nitride, chromium nitride, titanium nitride, tantalum nitride, molybdenum nitride, metal oxide, transparent electrically conductive material, or the like. For example, the connection part 240 is in a laminated structure made of metal including Ti/Al/Ti. The connection part 240, the source 227s and the drain 227d are made of the same material.

In some embodiments, a metal film layer where the connection part 240 is located further includes other metal components, such as a power wire, a signal wire, an electrical shielding component, and an opaque component, in order to fully utilize the metal film layer.

In some embodiments, the display panel 100 further includes one or more light-emitting devices 300 arranged on the array layer 200.

In some embodiments, the light-emitting devices 300 each are a light-emitting diode, for example, an inorganic light-emitting diode or a micro light-emitting diode (i.e., a micro-LED). The light-emitting device 300 is smaller than 200 microns in size. For example, the light-emitting device 300 is smaller than 100 microns or 50 microns.

Reference is made to FIG. 4, which is a schematic diagram illustrating the light-emitting device and the display panel that are partially enlarged according to an embodiment of the present disclosure. FIG. 4 only partially illustrates the array layer 200.

The light-emitting device 300 includes a main body 310 and a connection electrode 320. The main body 310 includes an N-type semiconductor layer 311, a P-type semiconductor layer 312, and an active layer 313 arranged between the N-type semiconductor layer 311 and the P-type semiconductor layer 312.

The main body 310 of the light-emitting device 300 forms a part of the light-emitting device 300 except for the connection electrode 320.

The main body 310 of the light-emitting device 300 is made of but is not limited to, a compound semiconductor such as gallium nitride (GaN), aluminum indium gallium phosphide (AlInGaP), aluminum gallium arsenide (AlGaAs), or gallium arsenide phosphate (GaAsP).

The connection electrode 320 includes a first electrode 321 and a second electrode 322. The first electrode 321 is electrically connected to the P-type semiconductor layer 312. The second electrode 322 is electrically connected to the N-type semiconductor layer 311. The first electrode 321 is positive, and the second electrode 322 is negative.

The connection electrode 320 is made of alloy or solid solution of gold (Au), tin (Sn), nickel (Ni), titanium (Ti), aluminum (Al), silver (Ag), and indium (In). For example, the connection electrode 320 is made of alloy gold and indium.

In some embodiments, the light-emitting device 300 is a vertically stacked micro light-emitting diode. That is, the first electrode 321 and the second electrode 322 are arranged on both sides of the main body 310, respectively. For example, when transfer-printing the light-emitting device 300 onto the array layer 200, the first electrode 321 of the light-emitting device 300 is bonded to the first connection part 241 on the array layer 200 by an eutectic process. In some embodiments, the display panel 100 further includes a first film layer 260. The first film layer 260 is at least partially arranged on the light-emitting device 300.

In some embodiments, the first film layer 260 is an insulation layer.

In some embodiments, the first film layer 260 is an organic film layer that covers a top surface and a side of the light-emitting device 300, to fill a gap between the light-emitting devices 300.

In some embodiments, the first film layer 260 is an adhesive layer, for example, optically clear (OC) film.

In some embodiments, openings OP are formed on the first film layer 260. At least some openings OP overlap the respective light-emitting devices 300, that is, projections of some openings OP overlap respective projections of the light-emitting devices 300 in a direction (i.e., a third direction Z) perpendicular to a plane where the display panel 100 is located. In one embodiment, in the direction perpendicular to the plane where the display panel 100 is located, orthographic projections of the some openings OP overlap respective orthographic projections of the light-emitting devices 300.

In some embodiments, the display panel 100 further includes a first electrode 250 arranged on the first film layer 260.

In some embodiments, the first electrode 250 is a transparent electrically conductive layer ITO, to prevent the display of the light-emitting device 300 from being blocked.

According to the embodiments, the first film layer protects the light-emitting devices and stabilizes the light-emitting devices. Furthermore, in a case that the vertically stacked micro light-emitting diode serves as the light-emitting device, the first film layer also supports the electrode (i.e., the first electrode) at a side of the light-emitting device.

In some embodiments, the first electrode 250 is electrically connected to the light-emitting devices 300 through the some openings OP.

As shown in FIG. 4, at least the remaining openings OP do not overlap the light-emitting devices 300.

That is, the remaining openings OP are virtual openings.

In some embodiments, the opening OP described here is a through hole passing completely through the first film layer 260. That is, both sides of the first film layer 260 are in contact through the through hole OP. For example, the opening OP through which the first electrode 250 is connected to the light-emitting device 300 is the through hole.

In one embodiment, the hole OP is a blind hole, which does not pass completely through the first film layer 260. That is, the blind hole OP is a groove or notch, facing a side of the first film layer 260 away from the array layer 200.

Therefore, the remaining openings (i.e., the virtual openings) form an auxiliary structure to protect the light-emitting devices from damages resulted from excessively etching the opening OP through which the first electrode 250 is connected to the light-emitting device 300.

Reference is made to FIGS. 4, 5 and 6. FIG. 5 is a schematic diagram showing an active area partially enlarged as illustrated in FIG. 1 according to another embodiment. FIG. 6 is a schematic diagram partially showing the display panel in cross-section along a line AA′ as shown in FIG. 5. The cross-section is perpendicular to the plane where the display panel is located.

In some embodiments, the display panel includes multiple openings OP, and at least some of the multiple openings OP vary in size, shape, or depth.

It should be noted that the size of the opening OP in the present disclosure is a maximum diameter of the opening OP. That is, two diameters flush with each other in the same direction (parallel to the plane where the display panel is located) are different. Therefore, the openings can be adaptable to light-emitting devices emitting light in various colors, and various electrical connections can be stable and performs excellently.

It should be noted that a first direction X in the embodiments of the present disclosure is parallel to the plane where the display panel is located. There is also a second direction Y (not shown in the diagrams) in the present disclosure. In some embodiments, the second direction Y is parallel to the plane where the display panel is located and intersects with the first direction X.

It should be noted that the shape of the opening OP in the present disclosure is a shape, i.e., a contour of a projection of the opening OP in the third direction Z, that is, on the plane where the display panel is located.

It should be noted that a depth of the opening OP in the present disclosure is a length of the opening OP in the third direction Z, that is, a vertical distance from the top to the bottom of the opening.

In some embodiments of the present disclosure, the display panel 100 further includes an adhesive layer 700 and a cover plate 800.

In some embodiments, the adhesive layer 700 is arranged on a side of the first electrode 250 away from the light-emitting device 300. The cover plate 800 is arranged on a side of the adhesive layer 700 away from the light-emitting device 300, or is arranged on a top surface of the display panel 100.

In some embodiments, the adhesive layer 700 is optically-clear adhesive (OCA), or includes an encapsulating adhesive.

In some embodiments, the adhesive layer 700 covers the array layer 200 and is configured to encapsulate the light-emitting element 300.

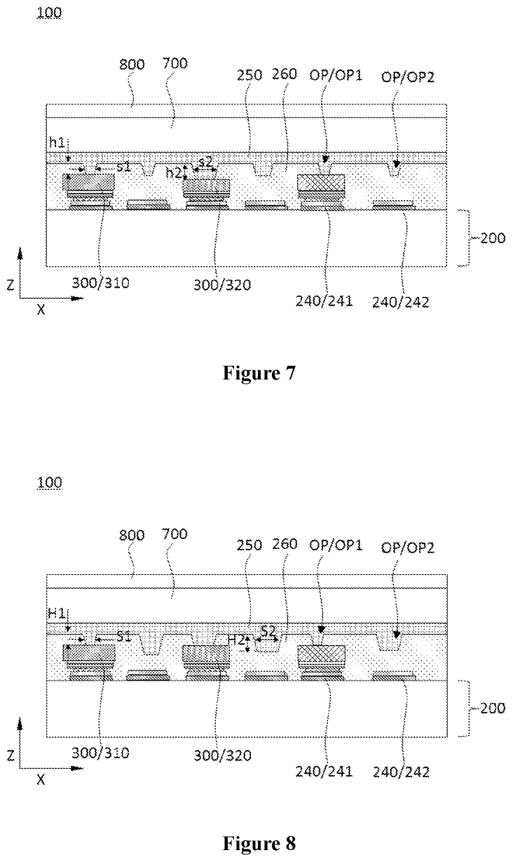

Reference is made to FIG. 7, which is a schematic diagram partially showing the display panel in cross-section along the line AA′ as shown in FIG. 5 according to another embodiment. In some embodiments, the opening through which one first electrode 250 is connected to the light-emitting device 300 emitting light in one color is different in depth from another opening through which another first electrode 250 is connected to another light-emitting device 300 emitting light in another color. Since the light-emitting device 300 emitting light in one color is different from another light-emitting device 300 emitting light in another color in thickness in a direction along which the layers are stacked (i.e., the third direction Z). Therefore, openings in various depths are defined to adapt to the light-emitting devices emitting light in various colors.

In some embodiments of the present disclosure, the openings corresponding to the light-emitting devices emitting light in respective colors are patterned, e.g., etched separately.

In some embodiments, the light-emitting devices 300 include a first light-emitting device 310 and a second light-emitting device 320. An opening corresponding to the first light-emitting device 310 is h1 in depth, and an opening corresponding to the second light-emitting device 320 is h2 depth. h1 is less than h2.

In some embodiments, the first light-emitting device 310 is configured to emit blue or green light. The second light-emitting device 320 is configured to emit red light. The opening corresponding to the second light-emitting device 320 is deeper than the opening corresponding to the first light-emitting device 310.

In some embodiments, the opening through which one first electrode 250 is connected to the light-emitting device 300 in one color is different in diameter from another opening through which another first electrode 250 is connected to another light-emitting device 300 in another color. The opening corresponding to the first light-emitting device 310 is s1 in diameter. The hole corresponding to the second light-emitting device 320 is s2 diameter. s1 is less than s2.

In this way, the light-emitting device 300 in one color is different in contact area with the first electrode 250 from another light-emitting device 300, which is adaptable to the light-emitting devices varying in luminous efficiency or characteristics.

In some embodiments, the opening through which one first electrode 250 is connected to the light-emitting device 300 emitting light in one color is different in both depth and diameter from another opening through which another first electrode 250 is connected to another light-emitting device 300 emitting light in another color.

Since the opening through which one first electrode 250 is connected to the light-emitting device 300 emitting light in one color is different in depth from another opening through which another first electrode 250 is connected to another light-emitting device 300 emitting light in another color, the former is also different in diameter from the latter in order to stably connect the first electrodes to the respective light-emitting devices and prevent the first electrode from being cut or broken during the fabricating process.

In some embodiments, one opening that is deeper is also greater than another opening that is shallower in diameter. For example, the opening corresponding to the second light-emitting device 320 is greater than the opening corresponding to the first light-emitting device 310 in both depth and diameter.

As shown in FIG. 7, the openings OP are divided into first openings OP1 and second openings OP2.

In some embodiments, the first opening OP1 overlaps the light-emitting device 300. The second opening OP2 does not overlap the light-emitting device 300. The first opening OP1 is for exposing the light-emitting device 300, and the first electrode 250 is connected to the light-emitting device 300.

Reference is made to FIG. 2, FIG. 4, or FIG. 8. FIG. 8 is a schematic diagram partially showing the display panel in cross-section along the line AA′ as shown in FIG. 5 according to another embodiment. In some embodiments, the first opening OP1 is different from the second opening OP2 in size, shape, or depth.

In some embodiments, the first opening OP1 is different from the second opening OP2 in maximum diameter. That is, the two maximum diameters that are flush with each other in the same direction (parallel to the plane where the display panel is located) are different.

In some embodiments, a projection of the first opening OP1 in the third direction Z is different in shape from a projection of the second opening OP2 in the third direction Z.

In some embodiments, the first opening OP1 is different in size from the second opening OP2 in the third direction Z.

In some embodiments, the first opening OP1 is less than the second opening OP2 in depth. On the one hand, the first opening is shallower to prevent the first film layer from being excessively etched, to avoid adverse effects on a surface of the light-emitting device and even damage to the light-emitting device. On the other hand, the second opening corresponding to a redundant electrode is deeper, to effectively improve the flexibility and the reliability of the display panel. Further, all the second openings are etched by the same process, and are etched deeper to facilitate connection between a substitute light-emitting device and the first electrode. Therefore, signals can be transmitted stably. As shown in FIG. 8, a depth H1 of the first opening OP1 is less than a depth H2 of the second opening OP2, that is, the first opening OP1 is longer than the second opening OP2 in the third direction Z. Therefore, the auxiliary function of the second opening can be further improved without affecting the light-emitting device, and the fabricating process can be simplified.

In some embodiments, the depth H1 of the first opening OP1 is less than the depth H2 of the second opening OP2. The first opening OP1 is less than the second opening OP2 in maximum diameter. An opening that is larger in diameter is etched deeper, to reduce the difficulty in the etching process.

In some embodiments of the present disclosure, the depth H1 of the first opening OP1 is less than the depth H2 of the second opening OP2. The first opening OP1 and the second opening OP2 are equal in maximum diameter. That is, although different in depth, the first opening OP1 and the second opening OP2 are equal or roughly equal in maximum diameter, and therefore can be etched simultaneously, to reduce costs and time spent on the etching.

In some embodiments, the depth H1 of the first opening OP1 is less than the depth H2 of the second opening OP2. A side wall of the first opening OP1 is greater than a side wall of the second opening OP2 in inclination angle. The inclination angle is an angle between the side wall of the opening and the plane parallel to the display panel. The side wall of the opening that is shallower is steeper than that of the deeper, to simplify the etching process and reducing costs.

As shown in FIG. 8, the first opening OP1 is less than the second opening OP2 in maximum diameter. In this way, an auxiliary opening (i.e., the second opening) is defined between light-emitting devices, to make full use of the gap between light-emitting devices, and further simplifying the fabricating process.

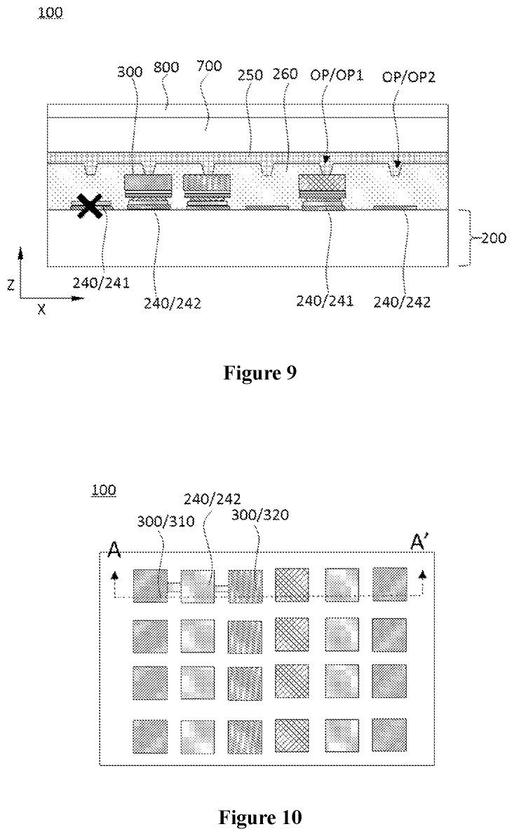

Reference is made to FIG. 9, which is a schematic diagram partially showing the display panel in cross-section along the line AA′ as shown in FIG. 5 according to another embodiment. The cross-section is perpendicular to the plane where the display panel is located.

In some embodiments, at least one second opening OP2 is arranged directly above a redundant electrode 242.

In some embodiments, the connection part 240 includes the first connection part 241 and the redundant electrode 242. That is, the first connection part 241 and the redundant electrode 242 are arranged on the same layer and made of the same material.

In some embodiments, the redundant electrode 242 is connected to the first connection part 241, to form an electrode group, corresponding to light-emitting devices 300 emitting the same color.

In some embodiments, a light-emitting device 300 when malfunctioned is removed, and the redundant electrode 242 corresponding to this light-emitting device 300 is bound to another light-emitting device 300 emitting the same color as the removed light-emitting device 300.

For example, the light-emitting device 300 corresponding to the first connection part 241, when malfunctioned (e.g., failing to emit light, or emitting light of insufficient brightness), i.e., when a defective pixel is resulted, is removed. Then, another light-emitting device 300 emitting the same color as the removed light-emitting device 300 is bound to the redundant electrode 242, and therefore the defective pixel can be repaired. The display panel 100 is subsequently subjected to encapsulation and other processes, which are well-known in the art and thus are not detailed herein.

In some embodiments, the first connection part 241 is disconnected from the redundant electrode 242 instead of removing the malfunctioning light-emitting device, to prevent the malfunctioning light-emitting device from affecting the substitute light-emitting device.

A redundant electrode not for the repairing is made of material slightly different from the connection part, due to the absence of eutectic process. That is, the redundant electrode 242 corresponding to the first opening OP1 is made of material slightly different from the first connection part 241 or redundant electrode 242 configured to be connected to no light-emitting device.

In some embodiments, at least one second opening OP2 is arranged directly above the first connection part 241.

It should be noted that FIG. 5 fails to show the substitute light-emitting device corresponding to the redundant electrode after the malfunctioning light-emitting device is removed. Therefore, reference is mainly made to FIG. 9 for these embodiments.

According to these embodiments, the auxiliary function of the second opening in the above embodiments is achieved, and some of the second openings serve as the substitutes of the first opening during the process.

After examined and repaired, the light-emitting device is covered with the first film layer, which is etched above the light-emitting device to form the opening, and the first electrode can be connected to the light-emitting device (that is, the second electrode 322). According to the conventional technology, the substitute redundant electrode fails to be positioned due to the failure to position the defective pixel, resulting in failure to position the opening to be defined by etching the first film layer. In the embodiments of the present disclosure, however, the malfunctioning light-emitting device is provided with the opening and its redundant electrode (or a redundant electrode of a light-emitting device highly prone to malfunction) is also provided with the opening. That is, the first film layer is etched directly above the light-emitting device and its redundant electrode, and thus one MASK is enough. Therefore, it is unnecessary to etch the first film layer directly above redundant electrode of the substitute light-emitting device due to the failure to position the malfunctioning light-emitting device during the examination and repairing, that is, no additional MASK is involved.

FIG. 10 is a schematic diagram the active area partially enlarged according to another embodiment. FIG. 11 is a schematic diagram partially showing the display panel in cross-section along the line AA′ as shown in FIG. 10. The cross-section is perpendicular to the plane where the display panel is located.

In some embodiments, multiple light-emitting devices 300 share one redundant electrode 242.

In some embodiments, at least two second openings OP2 are arranged directly above the same redundant electrode 242, to not only repair the malfunctioning light-emitting device but also prevent excessive redundant electrodes of the display panel, to improve the display result.

As shown in FIGS. 10 and 11, the at least two second openings OP2 arranged directly above the same redundant electrode 242 vary in size, shape, or depth.

In some embodiments, the at least two second openings OP2 arranged directly above the same redundant electrode 242 vary in maximum diameter. That is, the at least two maximum diameters that are flush with each other in the same direction (parallel to the plane where the display panel is located) vary.

In some embodiments, respective projections of the at least two second openings OP2 arranged directly above the same redundant electrode 242 vary in shape, in the third direction Z.

In some embodiments, the at least two second openings OP2 arranged directly above the same redundant electrode 242 vary in size in the third direction Z.

For example, the at least two second openings OP2 arranged directly above the same redundant electrode 242 include a first sub-opening and a second sub-opening. A depth H′ of the first sub-opening is less than a depth H″ of the second sub-opening. That is, the first sub-opening is less than the second sub-opening in length in the third direction Z.

In this way, there is always a second opening whose size matches a light-emitting device among the light-emitting devices emitting different colors that share the same redundant electrode, to further improve the auxiliary function of the second opening without affecting the light-emitting device and simplifying the fabricating process.

For example, the first sub-opening is different from the second sub-opening in depth. The first sub-opening is S′ is diameter, and the second sub-opening is S″ in diameter. S′ is less than S″.

The light-emitting devices emitting different colors vary in contact area with the first electrode. Therefore, such settings can be adaptable to light-emitting devices varying in luminous efficiency or characteristics. There is always an opening whose size matches a light-emitting device among the light-emitting devices emitting different colors that share the same redundant electrode, and the light-emitting device can be in sufficient contact area with the first electrode.

In some embodiments, the at least two second openings OP2 arranged directly above the same redundant electrode 242 vary in both diameter and depth.

Since the opening through which one first electrode 250 is connected to the light-emitting device 300 in one color is different in depth from another opening through which another first electrode 250 is connected to another light-emitting device 300 in another color, the former is also different in diameter from the latter in order to stably connect the first electrodes to the respective light-emitting devices and prevent the first electrode from being cut or broken during the fabricating process.

In some embodiments, one opening that is deeper is also greater than another opening that is shallower in diameter. For example, the opening corresponding to the light-emitting device emitting red light is greater than the opening corresponding to the light-emitting device emitting blue or green light both depth and diameter.

Furthermore, among the at least two second openings OP2 arranged directly above the same redundant electrode 242, the second opening (i.e., the first sub-opening) that is smaller in diameter or depth is adjacent to the first light-emitting device 310, and the second opening (i.e., the second sub-opening) that is larger in diameter or depth is adjacent to the second light-emitting device 320.

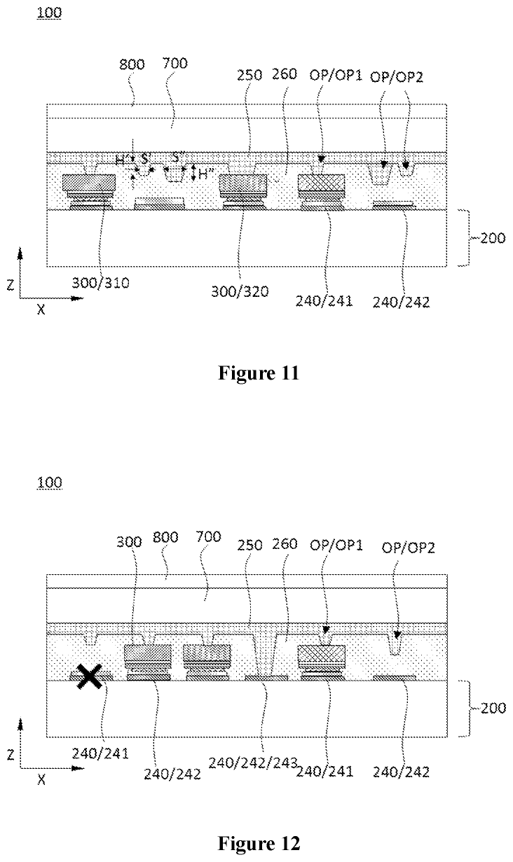

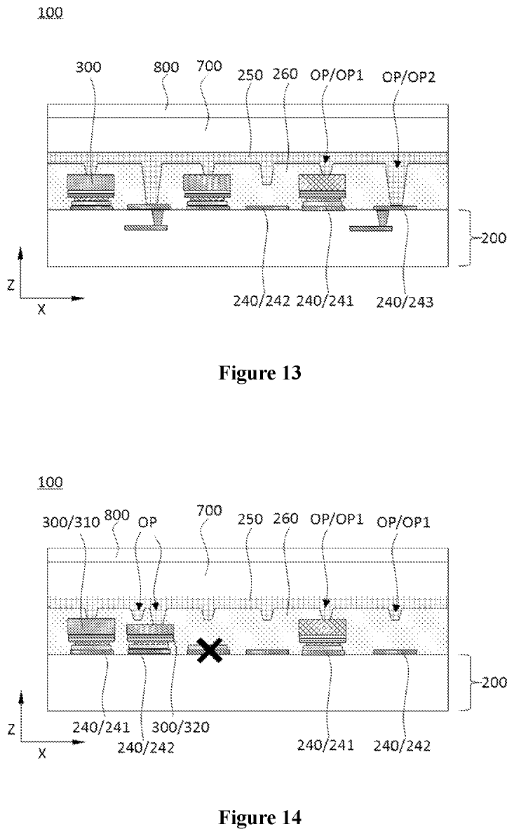

FIG. 12 and FIG. 13 each are a schematic diagram partially showing the display panel in cross-section along the line AA′ as shown in FIG. 5 or 10.

In some embodiments, at least one second opening OP2 is arranged directly above a jumper electrode 243, and for exposing the jumper electrode 243. The jumper electrode 243 and the redundant electrode 242 are arranged on the same layer and made of the same material.

In some embodiments, the connection part 240 includes the first connection part 241, the redundant electrode 242, and the jumper electrode 243. That is, the first connection part 241, the redundant electrode 242, and the jumper electrode 243 are arranged on the same layer and made of the same material.

In some embodiments, the second opening OP2 is a through hole. The first electrode 250 is in contact with the jumper electrode 243 through the second through hole OP2. Therefore, the resistance of the first electrode 250 can be reduced and thus the performance of the display panel can be improved.

In some embodiments, as shown in FIG. 12, some of the redundant electrodes 242 are disconnected from the respective first connection parts 241, to function as the jumper electrodes 243. The first connection part 241 corresponding to the malfunctioning light-emitting device is disconnected from the redundant electrode 242 corresponding to the substitute light-emitting device by the existing process. Therefore, the resistance of the first electrode 250 can be reduced, the fabricating process can be simplified, and the costs can be reduced. Further, no additional film layer is involved.

As shown in FIG. 13, in some embodiments, the jumper electrode 243 is connected to the signal wire or the power wire in the array layer 200. A signal is provided for the first electrode 250 by the jumper electrode 243. According to the embodiments, the problem of non-uniform signal of the first electrode 250 can be solved, to improve the display result, simplifying the fabricating process, and reducing the costs. Further, no additional film layer is involved.

Reference is made to FIG. 14, which is a schematic diagram partially showing the display panel in cross-section along the line AA′ as shown in FIG. 5 or 10.

In some embodiments, at least two openings OP are arranged directly above one light-emitting device 300. At least one of the at least two openings OP is a through hole, and at least one of the at least two openings OP is a blind hole.

In some embodiments, the light-emitting device 300 is connected to the first electrode 250 through the through hole OP.

In some embodiments, the light-emitting device 300 is the substitute light-emitting device, that is, arranged directly above the redundant electrode 242.

In some embodiments, the at least two openings OP vary in diameter and depth.

For example, the at least two openings OP arranged directly above the same light-emitting device 300 vary in maximum diameter, That is, the at least two maximum diameters that are flush with each other in the same direction (parallel to the plane where the display panel is located) vary. Respective projections of the at least two second openings OP2 arranged directly above the same light-emitting device 300 vary in shape, in the third direction Z. The at least two openings OP arranged directly above the same light-emitting device 300 vary in size in the third direction Z.

In some embodiments, the redundant electrode 242 described above is a common redundant electrode, that is, the redundant electrode is a backup pad electrode for the light-emitting devices varying in emitted colors.

In some embodiments, openings varying in depth that correspond to the same redundant electrode and the first openings corresponding to the light-emitting devices varying in emitted colors are fabricated by the same MASK.

According to the embodiments, respective openings matching the light-emitting devices varying in emitted colors are defined directly above the same redundant electrode, to simplify the fabricating process and reducing the costs. Further, no additional film layer is involved.

In other embodiments of the present disclosure, at least one opening OP is defined directly above the redundant electrode 242. Among the one or more openings OP, there is at least one opening having the same depth, diameter and shape as the opening defined directly above the second light-emitting device.

In some embodiments, the second light-emitting device 320 is configured to emit red light.

In other words, at least one opening OP defined directly above the redundant electrode 242 and the first opening corresponding to second light-emitting device 320 are fabricated by the same MASK. Since the opening defined directly above the light-emitting device configured to emit red light is greater than the light-emitting device configured to emit blue or green light in depth, the opening matching the light-emitting device configured to emit red light cam match the light-emitting device configured to emit light in other colors. According to the embodiments, the opening defined directly above the redundant electrode and the first opening is fabricated by the same MASK. Therefore, the substitute light-emitting device can be stably connected to the first electrode, to further simplify the fabricating process and reducing the costs.

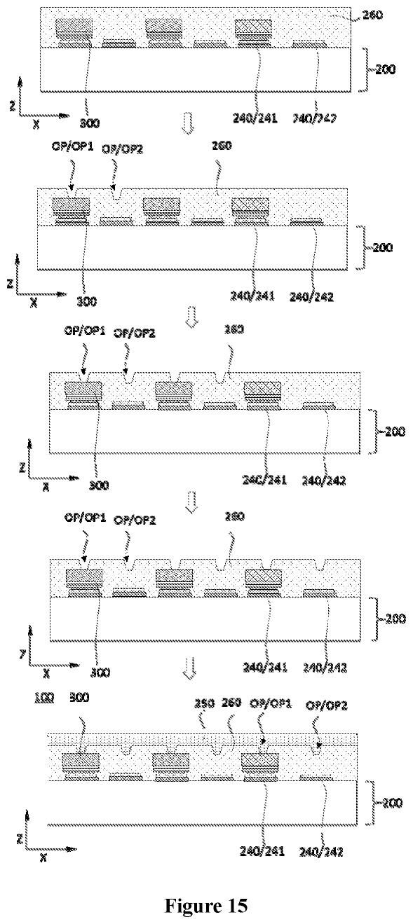

Reference is made to the above Figures together with FIG. 15, which is a schematic diagram illustrating the patterning of openings according to an embodiment, that is, a cross-section of the display panel during the fabricating process according to the present discourse.

In some embodiments, a method for fabricating the display panel according to the present discourse includes: providing an array layer 200; arranging one or more light-emitting devices 300 on the array layer 200; arranging a first film layer 260 on the light-emitting devices 300; forming openings OP on the first film layer 260, where at least some of the openings OP overlap the respective light-emitting devices 300; and arranging a first electrode 250 on the first film layer 260.

In some embodiments, the openings OP are divided into first openings OP1 and second openings OP2. The first opening OP1 overlaps the respective light-emitting device 300. The second opening OP2 does not overlap the light-emitting device 300.

The forming the openings OP on the first film layer 260 includes: at least forming some second openings OP2 and the first openings OP1 simultaneously.

In some embodiments, respective openings OP directly above the redundant electrode 242 and the first connection part 241 that are provided for the light-emitting devices emitting light in the same color are defined by the same MASK, that is, simultaneously. In other words, the second opening OP2 and the first opening OP1 provided for the light-emitting devices 300 emitting light in the same color are formed simultaneously. It should be noted that the light-emitting device 300 here indicates the light-emitting device corresponding to the connection part 240 that the second opening OP2 is arranged directly above.

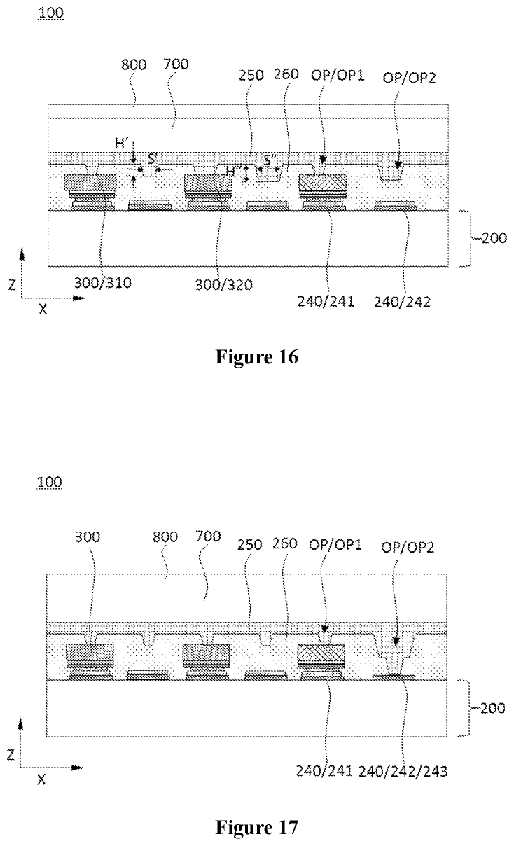

Reference is made to FIG. 16, which is a schematic diagram partially showing the display panel in cross-section along the line AA′ as shown in FIG. 15. The cross-section is perpendicular to the plane where the display panel is located.

In some embodiments, at least two second openings arranged directly above respective redundant electrodes vary in size, shape, or depth.

In some embodiments, the opening defined directly above one redundant electrode 242 corresponding to one light-emitting device 300 in one color is different in diameter, shape or depth from another opening defined directly above another redundant electrode 242 corresponding to another light-emitting device 300 in another color.

In other embodiments, the second openings varying in diameter, shape or depth are unnecessarily limited to the redundant electrodes. That is, any two second openings are different in diameter, shape, or depth.

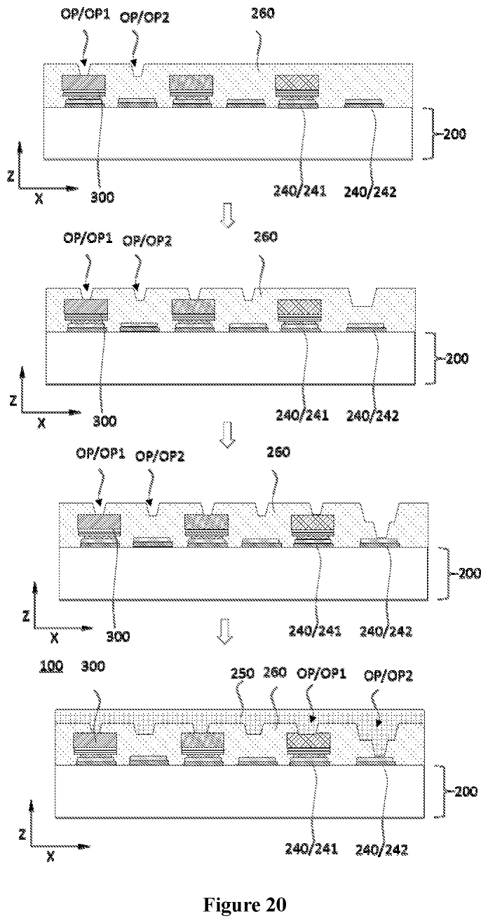

FIGS. 17 to 19 each are a schematic diagram partially showing the display panel in cross-section along the line AA′ as shown in FIG. 5 or 10. FIG. 20 is a schematic structural diagram of a patterned opening.

In some embodiments, at least one second opening OP2 has a step-shaped side wall. That is, the second opening OP2 is formed by stacking at least two openings varying in diameter.

In some embodiments, the second opening OP2 is arranged directly above the redundant electrode 242. The redundant electrode 242 functions as a substitute electrode for at least two light-emitting devices 300 emitting in different colors.

In some embodiments, as shown in FIG. 17, the second opening OP2 with the step-shaped side wall is a blind hole.

In some embodiments, the redundant electrode 242 functions as a jumper electrode.

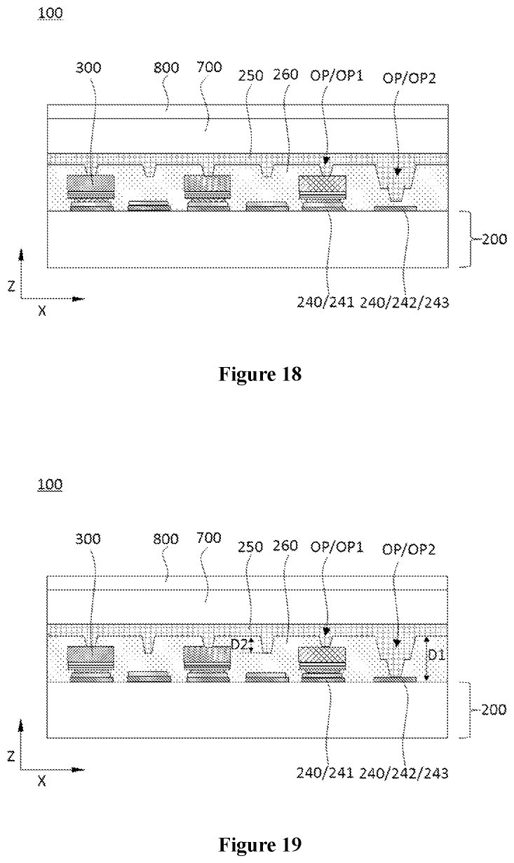

As shown in FIGS. 18 and 19, the second opening OP2 with the step-shaped side wall is a through hole. In this way, the first electrode is connected to the connection part 240 through the through hole. In conjunction with the embodiments shown in FIGS. 13 and 14 the resistance of the first electrode 250 can be reduced, the fabricating process can be simplified, and the costs can be reduced. Further, no additional film layer is involved. In addition, the first electrode through the second opening can be supported by the step, to improve the structural stability.

In some embodiments, as shown in FIG. 19, a distance from a top surface of the first film layer 260 to the redundant electrode 242 is D1. A distance from the top surface of the first film layer 260 to the light-emitting device 300 is D2, where D2<D1<3×D2. The openings for the light-emitting devices emitting light in different colors and the second opening are defined together. The openings corresponding to the light-emitting devices emitting light in different colors are defined by respective MASKs. The first film layer 260 directly above the second opening is etched multiple times, to form the second through hole finally. Therefore, the first electrode 250 can be connected to the jumper electrode 243, as show in FIGS. 19 and 20.

Reference is made to FIG. 20, which is a schematic diagram illustrating the display panel in cross-section during the fabricating process according to another embodiment. The forming openings OP on the first film layer 260 includes: forming at least one of the openings OP by two processes.

In some embodiments, the opening OP defined by two processes is the first opening OP1.

That is, the openings corresponding to the light-emitting devices emitting light in the same color are defined by respective MASKs. Patterns of the second openings on the MASKs coincide with each other. The first film layer directly above the second opening is etched multiple times, to form the second opening finally. Therefore, the first electrode 250 can be connected to the jumper electrode 243, without damaging the light-emitting device.

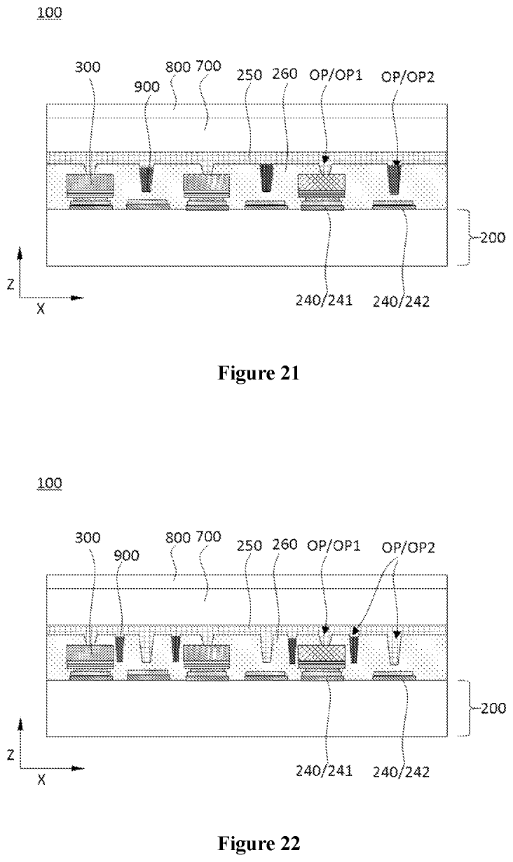

FIGS. 21 and 22 each are a schematic diagram partially showing the display panel in cross-section along the line AA′ as shown in FIG. 5 or 10.

In some embodiments, at least one second opening OP2 is defined between two light-emitting devices 300. Therefore, one second opening can provide the auxiliary function for more first openings without mutual influence between first openings.

In some embodiments, each first openings OP1 is adjacent to one second opening OP2, and the second opening can better provide the auxiliary function for the first opening.

In some embodiments, in the direction parallel to the display panel (i.e., in the third direction Z), the second opening OP2 overlaps the light-emitting device 300. In other words, the second opening OP2 is deeper than the first opening OP1, which can improve the auxiliary function provided by the second opening.

In some embodiments, at least one second opening OP2 is filled with opaque material or reflective material, which can avoid interfering light inside the display panel and avoid interference between adjacent light-emitting devices, to improve the display result.

As shown in FIG. 21, the second opening OP2 directly above the redundant electrode 242 (or the first connection part 241, not shown in FIG. 21) is filled with the opaque material, to reduce the impact of the redundant electrode 242 on the reflectivity of the display panel.

It should be noted that in some embodiments of the present disclosure, the redundant electrode functions as the electrode connected to the light-emitting device, and the opening directly above the first connection part corresponding to the substitute light-emitting device serves as the second opening. Therefore, in some embodiments, details about the redundant electrode are also applicable to the first connection part that corresponds to no light-emitting device.

As shown in FIG. 22, at least some second openings OP2 do not overlap the respective connection parts 240, and are filled with reflective material. Not only interference between adjacent light-emitting devices can be avoided, but also light emitted sideways from the light-emitting devices can be reflected back to make full use of the light, to improve the display result.

In some embodiments, at least a part of the second openings OP2 do not overlap with the connection part 240. The reflective material is filled in the part of the second openings OP2, which not only can avoid light crosstalk between adjacent light-emitting devices, but also can reflect back light emitted from sides of the light-emitting devices, improving light utilization efficiency, to improve the display result.

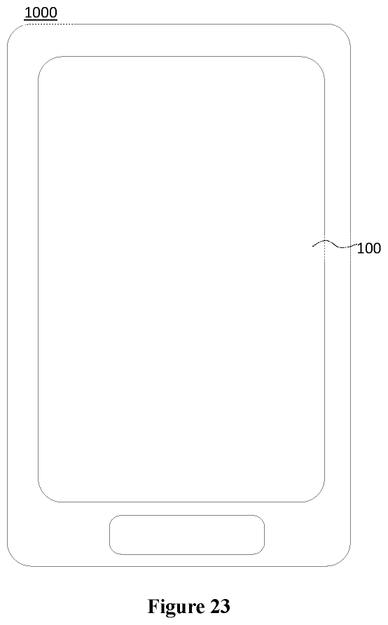

A display device is further provided according to the present disclosure. The display device includes the display panel according to the present disclosure. Reference is made to FIG. 23, which is a schematic structural diagram of the display device according to an embodiment of the present disclosure. The display device 1000 includes the display panel 100 according to any one of the foregoing embodiments of the present disclosure. In the embodiment illustrated in FIG. 23, the display device 1000 is, for example, a mobile phone. It should be understood that the display device according to the embodiments of the present disclosure is a computer, a television, a vehicle-mounted display device or other display device with a display function, which is not limited in the present disclosure. The display device according to the embodiments of the present disclosure has the same beneficial effects as the display panel according to the embodiments of the present disclosure, and therefore are not detailed herein.

The detailed description of the present disclosure is provided in combination with other embodiments. However, embodiments of the present disclosure are limited to the detailed description. All the deductions or substitutions should fall into the embodiments of the present disclosure.

What is claimed is:

1. A display panel, comprising
an array layer;
one or more light-emitting devices, arranged on the array layer;
a first film layer, at least partially arranged on the one or more light-emitting devices; and
a first electrode, arranged on the first film layer, wherein openings are formed on the first film layer, and at least part of the openings overlap the respective light-emitting devices.

2. The display panel according to claim 1, wherein
at least the openings do not overlap the light-emitting devices.

3. The display panel according to claim 1, wherein
at least the part of the openings vary in size, shape, or depth.

4. The display panel according to claim 1, wherein
the openings are divided into first openings and second openings, the first openings overlap with the respective light-emitting devices, and the second openings do not overlap the light-emitting devices.

5. The display panel according to claim 4, wherein
the first openings are different from the second openings in size, shape, or depth.

6. The display panel according to claim 5, wherein
the first openings are smaller than the second openings in depth.

7. The display panel according to claim 5, wherein
the first openings are smaller than the second openings in diameter.

8. The display panel according to claim 4, wherein
at least one of the second openings correspond to a redundant electrode.

9. The display panel according to claim 8, wherein
at least two of the second openings correspond to the same redundant electrode.

10. The display panel according to claim 9, wherein
the at least two second openings corresponding to the same redundant electrode vary in size, shape, or depth.

11. The display panel according to claim 4, wherein
at least one of the second openings corresponds to a jumper electrode, for exposing the jumper electrode, and the jumper electrode and a redundant electrode are arranged on a same layer and made of same material.

12. The display panel according to claim 4, wherein
at least two of the second openings correspond to respective redundant electrodes vary in size, shape or depth.

13. The display panel according to claim 4, wherein
at least one of the second openings is provided with a step-shaped side wall.

14. The display panel according to claim 1, wherein
the at least one of the second openings corresponds to a redundant electrode, and the redundant electrode doubles as a substitute electrode for at least two of the light-emitting devices configured to emit light in different colors.

15. The display panel according to claim 13, wherein
a distance from a top surface of the first film layer to a redundant electrode is D1, and a distance from the top surface of the first film layer to the light-emitting devices is D2, wherein D2<D1<3×D2.

16. The display panel according to claim 4, wherein
at least one of the second openings is arranged between two of the light-emitting devices.

17. The display panel according to claim 16, wherein
the second opening overlaps the light-emitting device in a direction parallel to the display panel.

18. The display panel according to claim 4, wherein
at least one of the second openings is filled with opaque material or reflective material.

19. The display panel according to claim 1, wherein
at least two of the openings correspond to the same light-emitting device, at least one of the openings is a through hole, and at least another of the openings is a blind hole.

20. The display panel according to claim 1, wherein
the light-emitting devices are vertically micro light-emitting diodes.

21. A display device, comprising:
the display panel according to claim 1.

22. A method for fabricating a display panel, comprising:
providing an array layer;
arranging one or more light-emitting devices on the array layer;
arranging a first film layer on the light-emitting devices;
forming openings on the first film layer, wherein at least part of the openings overlap the respective light-emitting devices; and
arranging a first electrode on the first film layer.

23. The method according to claim 22, wherein
the openings are divided into first openings and second openings, the first openings overlap with the respective light-emitting devices, and the second openings do not overlap the light-emitting devices, wherein the forming the openings on the first film layer comprises:
forming the first openings and at least part of the second openings simultaneously.

24. The method according to claim 22, wherein
the forming of the openings on the first film layer further comprises: forming at least one of the openings by two processes.
